(19) United States
(12) Patent Application Publication
(10) Pub. No.: US 2014/0153083 A1
(43) Pub. Date: Jun. 5, 2014

(54) RIN REDUCED OPTICAL SOURCE FOR OPTICAL COHERENCE TOMOGRAPHY

(71) Applicant: MASSACHUSETTS INSTITUTE OF TECHNOLOGY, (US)

(72) Inventors: Farhad Hakimi, Watertown, MA (US); John D. Moores, Groton, MA (US)

(73) Assignee: MASSACHUSETTS INSTITUTE OF TECHNOLOGY, Cambridge, MA (US)

(21) Appl. No.: 13/690,655

(22) Filed: Nov. 30, 2012

(51) Int. Cl. H01S 5/068

(52) U.S. Cl. CPC H01S 5/06817
USPC 359/337.2

(57) ABSTRACT

A relative intensity noise (RIN)-suppressed light source is provided that includes a light source that produces an incoming light. A semiconductor optical amplifier (SOA) arrangement receives the incoming light and provides a significant reduction in the RIN as its output. The SOA arrangement includes one or more SOAs in saturation that behave like a high pass filter for the amplitude of the incoming light.

### SPONSORSHIP INFORMATION

This invention was made with government support under Contract No. FA8721-05-C-0002, awarded by the U.S. Air Force. The government has certain rights in the invention.

### BACKGROUND OF THE INVENTION

The invention is related to the field of optical coherence tomography, and in particular to a relative intensity noise (RIN) reduced optical source for use in optical coherency.

Optical coherence tomography (OCT) is a powerful non-invasive non-contact cross-sectional imaging technique with high-resolution, applicable in many fields of science and engineering. OCT is similar to ultrasound imaging, which sends out ultrasonic waves and detects backreflection waves from a sample to form images. However, OCT has much higher resolution, superior image acquisition speed, and smaller instrument size. OCT applications include optical inspection of surfaces and subsurfaces, such as quality inspection of tablets in the pharmaceutical industry, measuring wafer and paper thickness, characterization of photoresists, identifying defects in precious stones (jewelry), studies of polymers, assessment of quality and thickness of varnish layer over paint layers in paintings (art diagnostics), velocimetry of micro-channels in microfluids, distance measurement, data storage, and dentistry.

However, the dominant use of OCT and the related technique of angle-resolved low-coherence interferometry (a/LCI) is in clinical medicine and biology. Applications of OCT in this context include imaging the subsurface structure of tissues, three-dimensional imaging within biological tissues (histology), ophthalmology (retinal disorders), dermatology, cardiology, oncology, diagnosing diseases, and in vivo biopsy, to mention a few. Angle-resolved low-coherence interferometry supplements the capabilities of OCT with the measurement of scattering angles of incident broadband light to infer, using inverse scattering techniques, scatterer geometry, e.g. to measure the size of cell nuclei. There are estimated over 120 companies that make OCT-related products and 30 companies that make OCT imaging systems.

OCT techniques and be divided into two classes, namely time domain (TD-OCT) and frequency domain (FD-OCT). There are two designs of FD-OCT instruments: spectrometer based (SB) and sweep laser source (SS). Both time domain and frequency domain OCTs are common in industry. Typically, TD-OCT is used where higher image quality is required while FD-OCT methods have much faster readout speeds. TD-OCT and spectrometer-based FD-OCT use incoherent broadband light as their optical sources. However, conventional incoherent broadband optical sources suffer from relative intensity noise (RIN) that limits the performance of TD-OCT and FD-OCT imaging systems. A RIN-reduced incoherent broadband optical source would be an enabler for high quality imaging systems and faster image acquisition.

### SUMMARY OF THE INVENTION

According to one aspect of the invention, there is provided a relative intensity noise (RIN)-suppressed light source. The RIN-suppressed light source includes a light source that produces an incoming light. A semiconductor optical amplifier (SOA) arrangement receives the incoming light and provides a significant reduction in the RIN as its output.

According to another aspect of the invention, there is provided a method of performing relative intensity noise (RIN) suppression. The method includes providing a light source that produces an incoming light. Also, the method includes receiving the incoming light using a semiconductor optical amplifier (SOA) arrangement that provides a significant reduction in the RIN at its output. The SOA arrangement includes one or more cascaded SOAs in saturation that collectively behave as a high pass filter for the time-varying amplitude of the incoming light.

### BRIEF DESCRIPTION OF THE DRAWINGS

FIG. 1 is a schematic diagram illustrating a Michelson interferometer with a translating mirror reference arm and a sample arm to create 3-D layered images;

FIGS. 2A and 2B are schematic diagrams illustrating two types of FD-OCT used in accordance with the invention;

FIG. 3 is a graph illustrating the signal to noise ratio (SNR) as a function of reference power of TD-OCT;

FIG. 4 is a schematic diagram illustrating a SOA operating in the saturating region (output optical power saturating as a function of input optical power) as a means of significant RIN reduction;

FIG. 5 is a graph illustrating the high pass filtering behavior of a SOA used in accordance with the invention.

FIGS. 6A and 6B are schematic diagrams illustrating various setups for RIN measurement used in accordance with the invention;

FIG. 7 shows graphs illustrating RIN reduction for EDFA-SOA and EDFA-SOA-SOA optical sources; and

FIG. 8 is a schematic diagram illustrating a double-pass configuration arrangement 100 used in accordance with the invention.

### DETAILED DESCRIPTION OF THE INVENTION

The invention involves a low RIN light source capable of significantly improving image quality and speed of TD-OCT and FD-OCT imaging systems. By using an optical source having one or more saturated semiconductor optical amplifiers (SOAs), it provides a compact, efficient, and low complexity RIN-suppressed optical source for TD-OCT and SB-OCT. The use of RIN suppression by means of a deeply saturated SOA cascade in the context of OCT applications is novel and appears to have been overlooked. Furthermore, the degree of RIN suppression is significant and is predicted to lead to as much as 10-13 dB SNR improvement in TD-OCT (resolution or data acquisition speed).

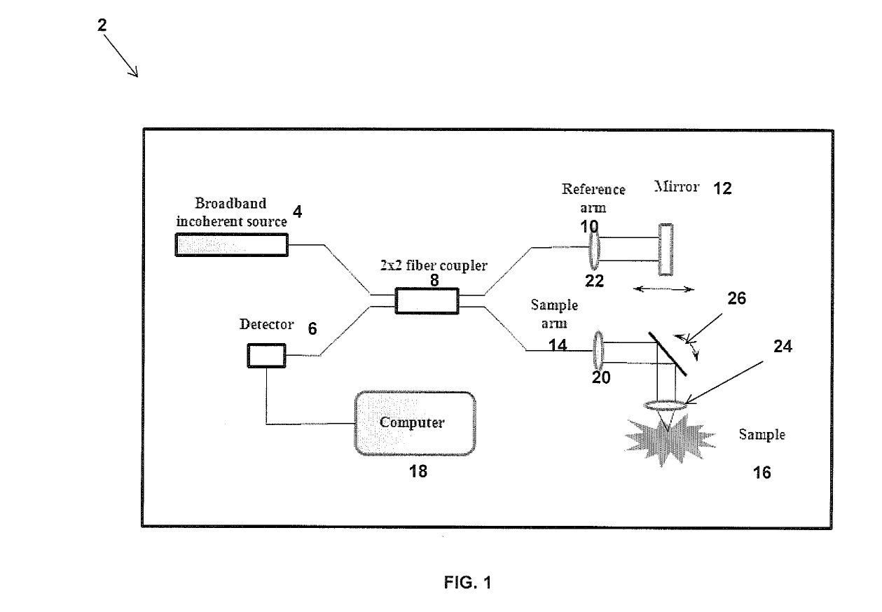

TD-OCT is a noninvasive, non-contact imaging technique that uses a broadband incoherent source of non-ionizing radiation to create cross-sectional images of biological tissues with high resolution on the order of a few microns. FIG. 1 shows a typical TD-OCT measurement setup 2. A Michelson interferometer is used to split a beam into a reference arm 10 and sample arm 14. The sample arm 14 has a lens 20 that focuses the light and sweeps across on a sample 16 while collecting the backscattered radiation. The reference arm 10 includes a lens 22 and a traveling mirror 10 functioning as tunable delay line. The reflected light from the reference and sample arms 10, 14 are mixed on the photodetector 6 to create fringes. Three dimensional images can be constructed by data from scanning mirror 26 across the sample 16 by measuring the echo time delay and intensity of the light back reflected from the sample 16 using a lens 24. A computer 18 receives this data to develop the three dimensional images, as shown in FIG. 1. Fiber-optic Michelson interferometers 8 are generally used for implementation an OCT systems. Common choices for broadband optical sources include erbium-doped fiber amplifiers (EDFAs) or superluminescent semiconductor diodes (SLDs). Other broadband incoherent sources could be used, including a number of different doped fiber optical amplifiers.

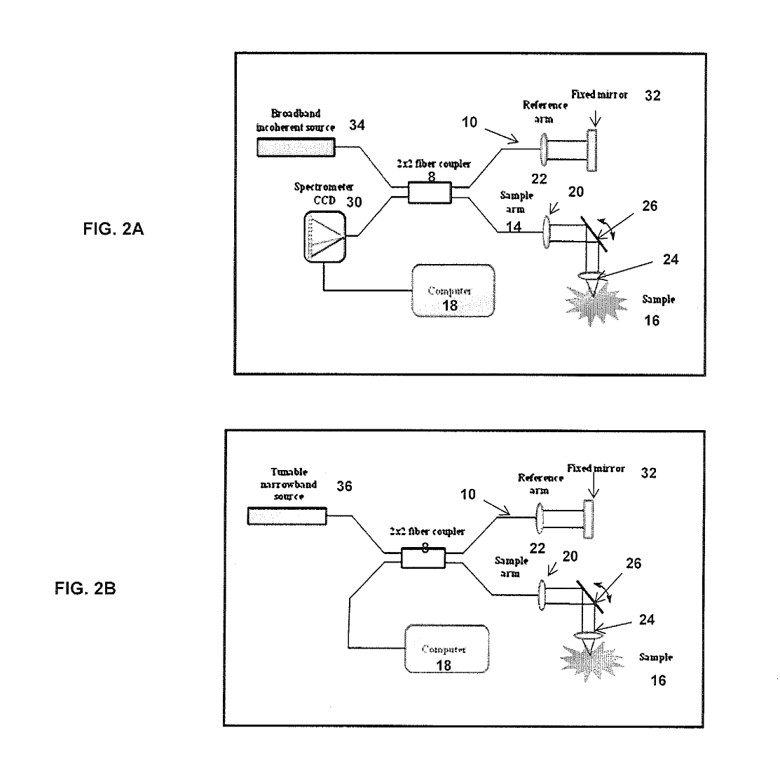

FIGS. 2A and 2B illustrate two types of FD-OCT, namely SB-OCT and SS-OCT, respectively. Unlike TD-OCT, the reference mirrors 32 are non-translating, as shown in the FIGS. 2A and 2B. SB-OCT uses broadband incoherent light 34 and a spectrometer together with a detector array (such as CCD) 30 to form the images, as shown in FIG. 2A. On the other hand, SS-OCT uses a narrowband tunable light source 36 scanning through the wide spectrum to form the image.

Sensitivity is a measure of the smallest sample reflectivity or backscattering cross section that can be resolved. OCT sensitivity is measured in signal-to-noise ratio (SNR) where the signal returned from a sample under study is interfered with the reference arm. The following SNR expression illustrates the signal (numerator) and noise terms (denominator). The three terms in the denominator represent electronic receiver noise, photon shot noise, and relative intensity noise (RIN), respectively.

$$SNR = \frac{2 {R}^{2} {P}_{ref} {P}_{sample}}{\frac{4 kT Δ f}{{Z}_{eff}} + 2 e {RP}_{ref} Δ f + ( RIN ) {R}^{2} {P}_{ref}^{2} Δ f}$$

where R is the detector responsivity, P_{ref} is the optical power contribution from the reference arm, Pₛₐₘₚₗₑ is the backscattered optical power from the sample, Z_{eff} is the detector impedance, and Δf is the detection electrical bandwidth.

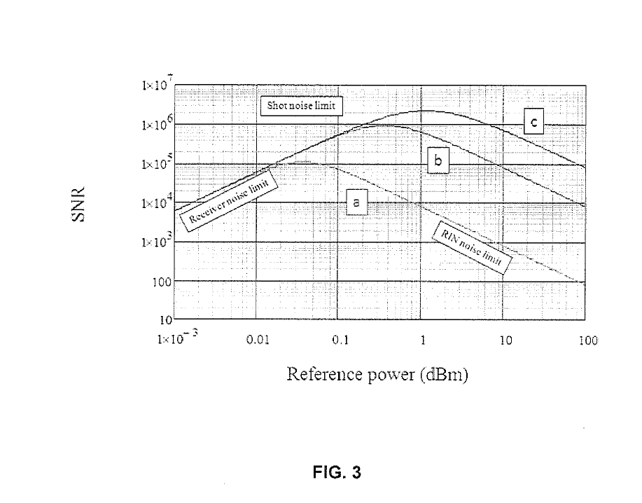

Source RIN generally dominates the denominator and governs the highest achievable SNR. The sensitivity of a TD-OCT is a factor determining the trade-off between image quality and image acquisition speed. A lower RIN source results in higher SNR, which leads to either higher image quality or faster image acquisition. FIG. 3 shows computed SNR as a function of reference arm power (Pref), in a TD-OCT setup with Psample=1 picoWatt, R=1 Amp/Watt, T=room temperature, Zeff=50 Ohms, RIN=optical source relative intensity noise, and Δf=image acquisition bandwidth of 1 Hz. Graph (a) depicts an incoherent source with 30 nm optical bandwidth (no RIN suppression), while Graphs (b) and (c) show RIN suppression of 20 dB and 30 dB for the same source, respectively.

There are three distinct regions as shown in graphs of FIG. 3. At low reference power, receiver noise is the main contributor while at high powers RIN is the dominant noise factor. Shot noise is the main contributor in between the receiver noise and RIN noise regions. The three graphs on the plot show that higher SNR is achieved with more highly RIN-suppressed sources. Furthermore, the price to pay for higher SNR using RIN suppressed sources is more optical power required from the reference arm of the interferometer. The optimum power requirements (maxima) of the reference arm for 20 dB is ˜350 μW while 30 dB RIN is ˜1 mW; these power levels are feasible in practical applications, using commercially available components. The RIN reduction of 20 dB and 30 dB result in 9.3 dB to 13.1 dB SNR improvement, respectively, as shown in FIG. 3.

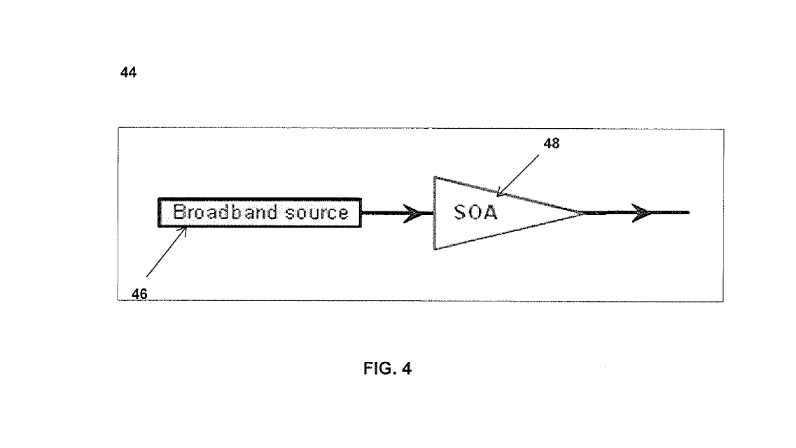

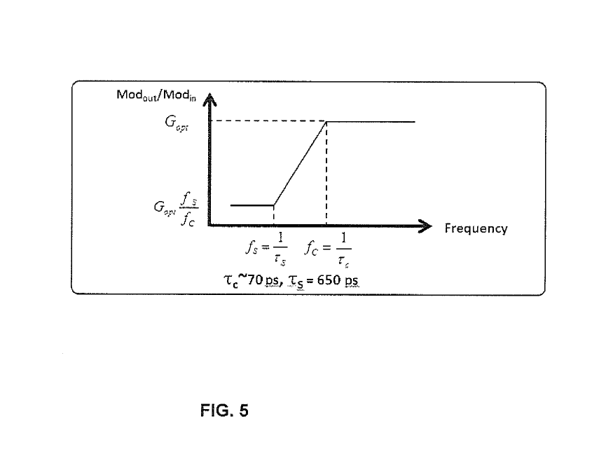

In an exemplary embodiment of the invention includes a low complexity means of optical RIN reduction for an OCT broadband source is an in-line semiconductor optical amplifier (SOA) operating in the saturation regime, downstream of the source. FIG. 4 depicts an OCT optical source 44, such as an erbium-doped fiber amplifier (EDFA), input to a SOA 48 operating in saturation. The saturated SOA 48 provides a significant reduction in the RIN of the output light. A SOA in saturation behaves like a high pass filter for the amplitude of the light, as shown in FIG. 5. That is to say, the SOA can pass high frequency amplitude fluctuations of the light largely unchanged, but can damp out low frequency amplitude fluctuations. The characteristic frequencies for such a high pass filter are f_{c} and f_{S}, where f_{c} is related to semiconductor carrier lifetime (τ_{c}) and f_{S} is connected to the stimulated emission in the SOA as well as carrier lifetime (τ_{S}=1/f_{S}). Carrier lifetime values are typically around 70 ps in semiconductors while τ_{S} is typically in the neighborhood of 700 ps, which places the rising high pass edge of SOA (maximum frequency of the most effective RIN suppression) slightly above 1 GHz.

Since OCT systems generally operate at modulation frequencies at 100 kHz or below, the SOA 48 can effectively dampen out the relevant amplitude fluctuations of the broadband source, with plenty of margin in the frequency response of the SOA 48. Therefore, following a broadband source (such as EDFA) with a saturated SOA can be an effective way of reducing RIN for OCT applications.

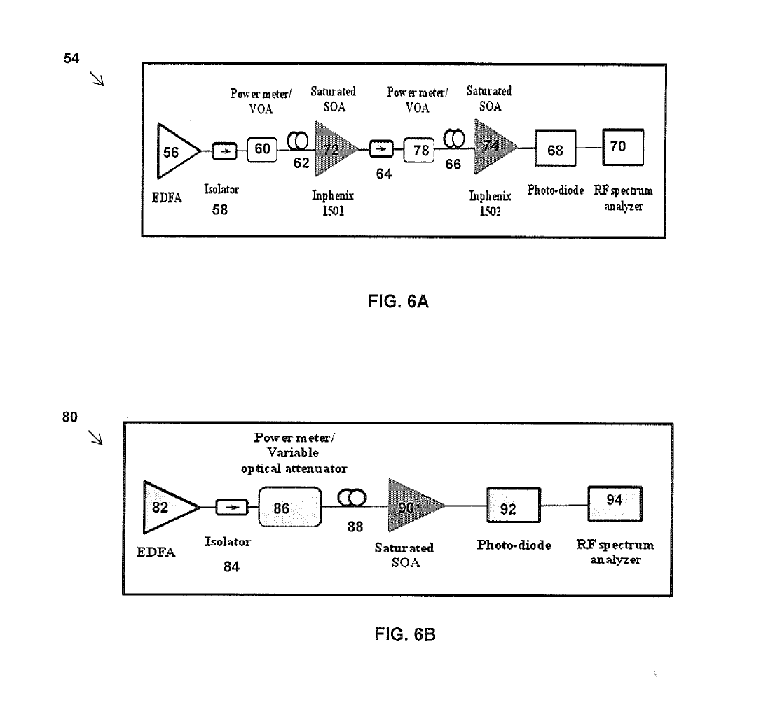

FIG. 6A shows an EDFA-SOA-SOA cascade arrangement 54 used to measure RIN having two SOAs 72, 74 (Inphenix 1501 and 1502) operating in the deep saturation region. FIG. 6A shows a light source 56 from a commercial EDFA providing light to two cascaded SOAs 72, 74 (Inphenix 1501 and 1502) using isolators 58, 64 and polarization controllers 62, 66. A high speed photodetector 68 and RF analyzer 70 are used to measure RIN. An RF amplifier with high gain and low noise can be used to boost the signal above the noise floor of the RF spectrum analyzer 70. Power meters 60, 78 having variable optical attenuation are positioned at the inputs of the SOAs 72, 74 to measure power.

FIG. 6B shows a cascaded EDFA-SOA arrangement 80 which uses a single SOA 90. In this implementation, the single SOA 90 can either be an Inphenix 1501 or 1502. For purposes of RIN measurement, the Inphenix 1501 and 1502 are used separately to provide separate RIN measurements as reference points. A light source 82 from a commercial EDFA provides light to the cascaded SOA 90 (Inphenix 1501 or 1502) using an isolator 84 and a polarization controller 88. A high speed photodetector 92 and a RF analyzer 94 are used to measure RIN. A tunable power meter 86 having variable attenuation is positioned at the outputs of the SOA 90 to measure power.

Although a SOA, or SOA cascade is a preferred embodiment for the RIN-suppression mechanism, any medium that exhibits saturation of output optical power with increasing input optical power, whether by transmission, refraction, scattering, or reflection, over a sufficient bandwidth for the measurement apparatus and methods to which the broadband source is being applied, would also be applicable to the invention. In other embodiments of the invention, SLDs can be used in place of the EDFAs to for cascaded SLD-SOA arrangements as well as cascaded SLD-SOA-SOA arrangements.

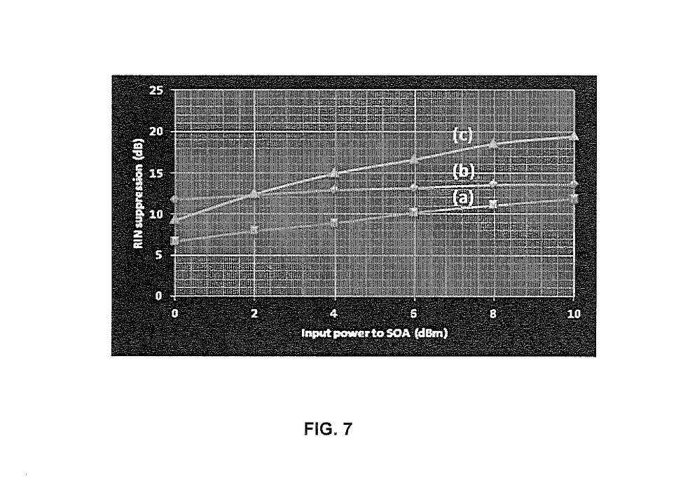

FIG. 7 shows the RIN measurements for the cascaded EDFA-SOA arrangement 80 (traces a and b) and EDFA-SOA-SOA arrangement 54 (trace c) as a function of input optical power. Trace (a) shows RIN suppression using the cascaded SOA arrangement 80 using Inphenix 1502 (2 mW saturated output power) while trace (b) depicts RIN suppression for the cascaded SOA arrangement 80 using Inphenix 1501 (10 mW saturated output power). Trace (a) and Trace (b) show with an injection of 10 mW, both the Inphenix 1502 and 1501 can produce 12 and 14 dB RIN suppression, respectively. It will be appreciated that the Inphenix 1502 is deeper into saturation than the Inphenix 1501 and shows a stronger dependence with input power. Trace (c) shows RIN suppression of 19.5 dB for the EDFA-SOA-SOA arrangement 54 which is even higher than the individual cascaded SOA cases discussed above, with 10 dBm input power launched into both SOAs 72, 74. Such a RIN suppressed source can be used to achieve a significant lowering of OCT as explained herein.

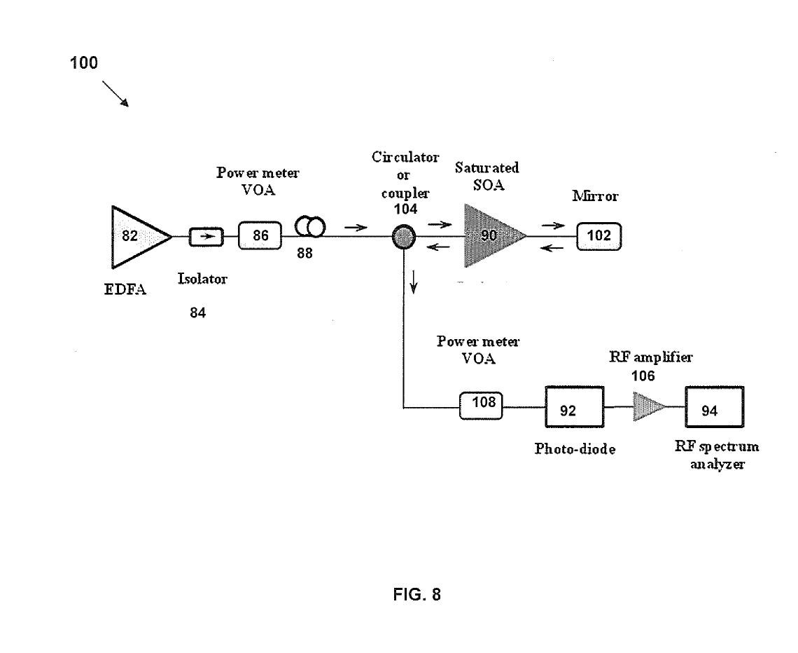

FIG. 8 shows a double-pass configuration arrangement 100 used in accordance with the invention. In particular, the double-pass configuration 100 may enhance RIN suppression by using one or more SOAs. The double-pass configuration 100 includes similar functional elements as described in FIG. 6B. However, a circulator or a coupler 104 is inserted at the input port while a reflector is included at the output port of SOA 90. A power meter 108 is connected to the circulator or coupler 104 to measure power of the signal. The reflector 102 at the output of the SOA 90 can be of the form of a coating directly deposited on the output facet of the SOA 90 or a fiber optic mirror (such as Faraday mirror) spliced as a fiber pigtailed SOA.

The double-pass configuration 100 can be cascaded or cascaded with single pass SOAs with a RF amplifier 106 having a high gain and low noise to boost the signal above the noise floor of the RF spectrum analyzer 94.

The invention provides a technique for RIN suppression by means of deeply saturated SOAs in the context of OCT applications. Furthermore, the degree of RIN suppression is significant and is predicted to lead to as much as 10-13 dB SNR improvement in TD-OCT (resolution or data acquisition speed). The invention provides arrangements where following an optical source one can position one or more saturated SOAs to provide a compact, efficient, and low complexity RIN-suppressed optical source for TD-OCT and SB-OCT.

Although the present invention has been shown and described with respect to several preferred embodiments thereof, various changes, omissions and additions to the form and detail thereof, may be made therein, without departing from the spirit and scope of the invention.

What is claimed is:

1. A relative intensity noise (RIN)-suppressed light source comprising:
a light source that produces an incoming light; and
a semiconductor optical amplifier (SOA) arrangement that receives the incoming light and provides a significant reduction in the RIN as its output, the cascaded SOA arrangement includes one or more SOAs in saturation that behave like a high pass filter for the amplitude of the incoming light.

2. The RIN-suppressed light source of claim 1, wherein the light source comprises a broadband light source.

3. The RIN-suppressed light source of claim 2, the broadband light source comprises erbium doped fiber amplifier (EDFA) or superluminescent semiconductor diodes (SLDs).

4. The RN-suppressed light source of claim 1, the SOA arrangement comprises a cascaded EDFA-SOA arrangement or cascaded SLD-SOA arrangement.

5. The RIN-suppressed light source of claim 1, the SOA arrangement comprises a cascaded EDFA-SOA-SOA arrangement or cascaded SLD-SOA-SOA arrangement.

6. The RIN-suppressed light source of claim 4, the cascaded EDFA-SOA arrangement or cascaded SLD-SOA arrangement comprises RIN-suppression of at least 12 dB.

7. The RIN-suppressed light source of claim 5, the cascaded EDFA-SOA-SOA arrangement or the cascaded SLD-SOA-SOA arrangement comprises RIN-suppression of at least 19.5 dB.

8. The RIN-suppressed light source of claim 1, the SOA arrangement dampens out the relevant amplitude fluctuations of the light source.

9. A method of performing relative intensity noise (RIN) suppression comprising:
providing a light source that produces an incoming light; and
receiving the incoming light using a semiconductor optical amplifier (SOA) arrangement that provides a significant reduction in the RIN as its output, the SOA cascaded arrangement includes one or more SOAs in saturation that behave like a high pass filter for the amplitude of the incoming light.

10. The method of claim 9, wherein the light source comprises a broadband light source.

11. The method of claim 10, the broadband light source comprises erbium doped fiber amplifier (EDFA).

12. The method of claim 9, the SOA arrangement comprises a cascaded EDFA-SOA arrangement or cascaded SLD-SOA arrangement.

13. The method of claim 9, the SOA arrangement comprises a cascaded EDFA-SOA-SOA arrangement or cascaded SLD-SOA-SOA arrangement.

14. The method of claim 12, the cascaded EDFA-SOA arrangement or cascaded SLD-SOA arrangement comprises RIN-suppression of at least 12 dB.

15. The method of claim 13, the cascaded EDFA-SOA-SOA arrangement or cascaded SLD-SOA-SOA arrangement comprises RIN-suppression of at least 19.5 dB.

16. The method of claim 9, the SOA arrangement dampens out the relevant amplitude fluctuations of the light source.
